(19) United States
(12) Patent Application Publication
(10) Pub. No.: US 2021/0400824 A1
(43) Pub. Date: Dec. 23, 2021

(54) ELECTRONIC DEVICE

(71) Applicant: TDK Electronics AG, Munchen (DE)

(72) Inventors: Fabian Beck, Ruttenen (CH); Zilong Kuang, Zhuhai (CN)

(21) Appl. No.: 17/330,134

(22) Filed: May 25, 2021

(30) Foreign Application Priority Data
Jun. 19, 2020 (DE) 102020116283.9

(51) Int. Cl. H05K 5/00; H01R 25/14; H02G 5/00; H03H 1/00

(52) U.S. Cl. CPC H05K 5/0026; H03H 1/0007; H02G 5/005; H01R 25/14

(57) ABSTRACT

The present invention concerns an electronic device (1) comprising a housing (2) and at least one electronic component (Cx, Cy, L) which is arranged inside the housing (2), wherein the housing (2) is suitable for feedthrough of at least one bus bar (6a, 6b), wherein the housing (2) is compatible with bus bars (6a, 6b) of different shapes.

The present invention concerns an electronic device and a system comprising the electronic device and two pairs of bus bars.

Electronic devices are often manufactured with integrated bus bars, e.g. copper bus bars. Existing electronic devices, however, suffer from a low flexibility to adapt to changes in the geometry of an interface to which the electronic device shall be connected.

It is an object of the present application to provide an improved electronic device, for example an electronic device which has an improved flexibility.

The object is solved by the subject-matter of claim 1.

An electronic device is provided which comprises a housing and at least one electronic component which is arranged inside the housing. The housing is suitable for feedthrough of at least one bus bar. The housing is compatible with bus bars of different shapes.

The bus bar itself is not part of the electronic device. Instead, the electronic device is configured to receive the bus bar. The bus bar can be inserted into the electronic device such that it protrudes from the electronic device. As the electronic device is compatible with bus bars of different shapes, the flexibility of the electronic device to adapt to changes in the geometry of an interface is large.

The electronic device can be a standardized electronic device wherein it is possible to combine the electronic device with a wide variety of interfaces by choosing an appropriate bus bar.

The housing can be adapted such that the housing imposes no restrictions of the shape of a terminal of the at least one bus bar. The terminal can be an end part of the bus bar which is configured to be connected to a power supply or an interface. The bus bar can be configured to apply a voltage from the power supply to the electronic components inside the housing when the bus bar is fed through the housing.

In one embodiment, the housing can comprise a guiding element suitable for feedthrough of the at least one bus bar, wherein the guiding element extends from a first end of the housing to a second end of the housing. The guiding element may be a tube. In another embodiment, the housing may be free from any guiding elements.

When the bus bar is arranged in the guiding element, the bus bar can simultaneously protrude from the first end and from the second end of the housing. The parts of the bus bar that protrude from the ends of the housing can be the terminals of the bus bar.

The housing can comprise a fixation element configured to fix the at least one bus bar after the at least one bus bar is inserted in the housing. The fixation element can fix the bus bar mechanically. For example, the fixation element can comprise a screw and/or a spring. Alternatively, the fixation element may comprise a clamp.

At least one of a capacitor and an inductor can be arranged in the housing as electronic components. The capacitor can be a Y-capacitor or an X-capacitor. The inductor can be a magnetic core which is arranged such that it surrounds the bus bars when the bus bars are fed through the housing. The inductor can be a magnetic core which surrounds the guiding element, e.g., the tube.

The electronic device can be free from an integrated bus bar. An integrated bus bar would limit the flexibility of the electronic device for connection to different interface geometries.

The electronic device may be an EMC filter.

The electronic device can comprise a connection point inside the housing. The at least one electronic component can be electrically connected to the connection point. The electronic device may be configured such that a bus bar that is fed through the housing is electrically connected to the connection point. The connection point may be a metallization at an inner wall of the guiding element. Via the connection point, a voltage and a current can be applied from the bus bar to the electronic components.

Another aspect concerns a system comprising the above-described electronic device, a first pair of bus bars and a second pair of bus bars. The first pair of bus bars and the second pair of bus bars differ in their shape. In particular, the first pair of bus bars and the second pair of bus bars may differ in the shape of their terminals. The housing of the electronic component is compatible with both the first pair of bus bars and the second pair of bus bars. The housing of the electronic component is suitable for feedthrough of the first pair of bus bars and for feedthrough of the second pair of bus bars.

Each bus bar of the first pair of bus bars may comprise a metallic stripe and a terminal arranged at a first angle to the metallic stripe. Each bus bar of the second pair of bus bars may comprise a metallic stripe and a terminal arranged at a second angle to the metallic stripe. The second angle may differ from the first angle.

For different applications and for connection to different customer interfaces, the electronic device can be connected either to the first pair of bus bars or to the second pair of bus bars depending on the geometry of the customer interface.

The same electronic component can be combined with different interfaces by selecting appropriate bus bars. No modifications of the electronic components are necessary.

In the following, preferred embodiments of the invention are described with reference to the Figures.

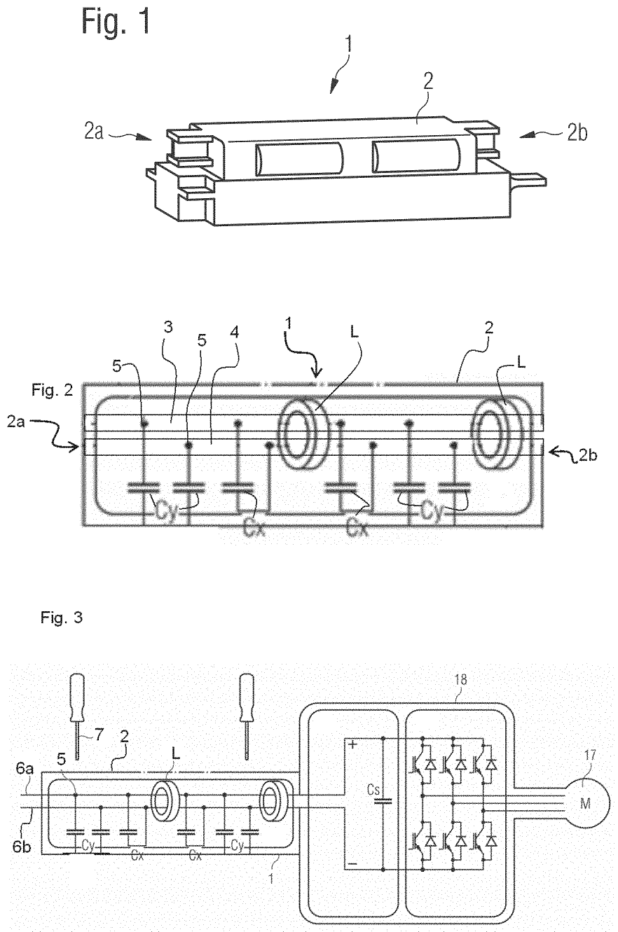

FIG. 1 shows an electronic device in a perspective view.

FIG. 2 shows the electronic device in a schematic view.

FIG. 3 shows an interconnection of the electronic device with a motor and an inverter.

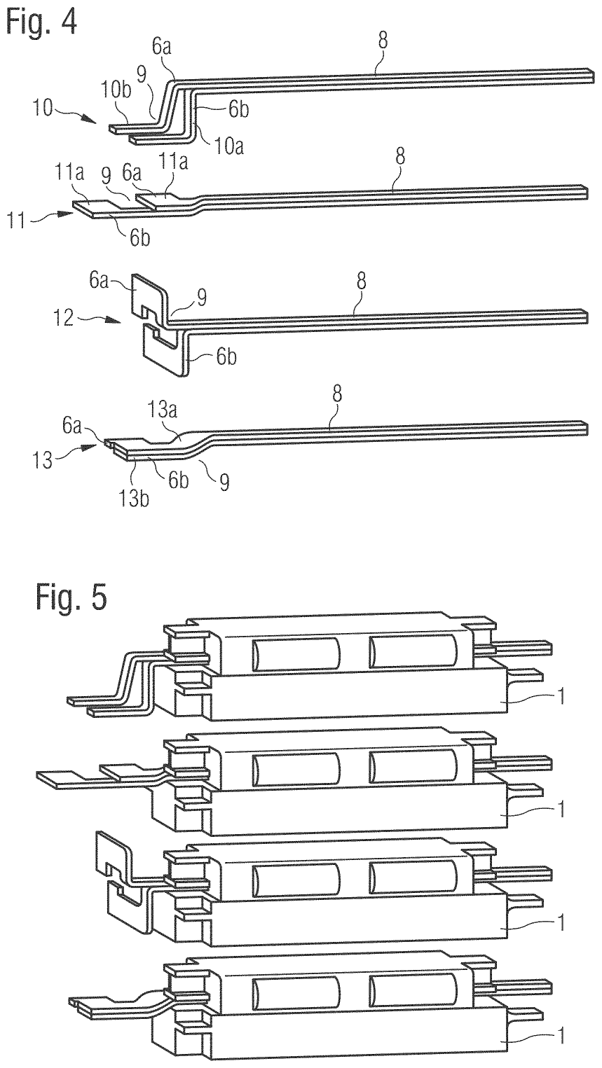

FIG. 4 shows a perspective view of four pairs of bus bars.

FIG. 5 shows an arrangement wherein the bus bars shown in FIG. 4 are fed through the electronic device shown in FIG. 1.

An electronic device 1 is shown in FIG. 1 and FIG. 2. The electronic device 1 is an EMC filter. The electronic device 1 comprises a housing 2 and electronic components Cy, Cx, L which are arranged inside the housing 2. In particular, capacitors Cy, Cx and inductors L are arranged inside the housing. The capacitors are Y capacitors and x capacitors. The electronic device can comprise a printed circuit board arranged inside the housing 2 wherein some of the electronic components Cy, Cx are arranged on the printed circuit board.

The housing 2 is suitable for feedthrough of a pair of bus bars. In particular, the housing comprises a first guiding element 3 and a second guiding element 4 which both extend from a first end 2a of the housing 2 to a second end 2b of the housing 2 which is opposite to the first end 2a. Each of the first guiding element 3 and the second guiding element 4 may comprise a tube. Each bus bar can be inserted into one of the guiding elements 3, 4. The bus bars can be inserted into the guiding elements 3, 4 such that one end of the bus bars protrudes from the first end 2a of the housing 2 and another end of the bus bars protrudes from the second end 2b of the housing 2.

The housing 2 comprises connection points 5. Each of the connection points 5 is electrically connected to one of the electronic components Cx, Cy in the housing 2. In particular, each of the connection points 5 is connected to one of the capacitors Cx, Cy. The housing 2 is adapted and arranged such that a bus bar is electrically connected to some of the connection points 5, when the bus bar is inserted into the housing 2.

In particular, the housing 2 comprises a first group of connection points 5 and a second group of connection points 5. The connection points 5 of the first group are arranged at an inner wall of the first guiding element 3. The connection points 5 of the second group are arranged at an inner wall of the second guiding element 4.

The housing 2 is adapted and arranged such that a first bus bar is electrically connected to the connection points 5 of the first group, when the first bus bar is inserted into the housing 2 and such that a second bus bar is electrically connected to the connection points 5 of the second group, when the second bus bar is inserted into the housing 2. A voltage can be applied to the electronic components Cx, Cy inside the housing 2 via the bus bars and the connection points Cx, Cy.

Insulation material and, optionally, resin can also be arranged inside the housing 2.

The housing 2 provides no restrictions regarding the shape of the terminals of the bus bars. Bus bars which differ in the shape of their terminals can be fixed to the housing 2. The housing 2 is compatible with a large variety of bus bars of different shapes.

FIG. 3 shows an interconnection of the electronic device shown in FIG. 2 with a motor 17 and an inverter 18.

The inverter 18 comprises a first bus bars 6a and a second bus bar 6b. The first bus bars 6a and the second bus bar 6b are fed through the electronic device 1. Each of the bus bars 6a, 6b is electrically connected to four connection points 5.

The contact between the bus bars 6a, 6b and the connection points 5 is closed via a spring-loaded connection 7, in particular a spring-loaded screw fastening. The spring-loaded connection 7 may cushion forces acting on the bus bars 6a, 6b and ensure that the forces are not transmitted to the electronic components Cx, Cy. In addition, the spring-loaded connection 7 may cushion the weight of the bus bars 6a, 6b and so mechanically relieve the load on the electronic components Cx, Cy.

FIG. 4 shows a perspective view of four pairs of bus bars 6a, 6b. Each of the bus bars 6a, 6b is configured to be fed through the housing 2 of the electronic device 1.

Each of the bus bars 6a, 6b comprises a main body and a terminal 9. The main body consists of a metallic stripe 8 which is shaped as a straight line. The terminal 9 is arranged at a first end of the main body which is configured to protrude from the first end 2a of the housing 2 when the bus bar 6a, 6b is fed through the housing 2.

Each of the four pairs of bus bars 6a, 6b has an identical main body formed by the metallic stripe 8 and each of the four pairs of bus bars 6a, 6b differs from the other pairs in the shape of the terminal 9. For each of the four pairs of bus bars 6a, 6b, the respective terminal 9 differs in its shape from the shape of the straight metallic stripe 8 which forms the main body.

In the first pair 10 of bus bars 6a, 6b, the terminal 9 comprises a first section 10a and a second section 10b. The first section 10a of the terminal 9 is adjacent to the metallic stripe 8 of the main body. The second section 10b of the terminal 9 is adjacent to the first section 10a. Accordingly, the first section 10a is arranged between the second section 10b and the metallic stripe 8.

The first section 10a is perpendicular to the metallic stripe 8. The second section 10b is parallel to the metallic stripe 8. The first section 10a provides an offset of the second section 10b relative to the metallic stripe 8.

In the second pair 11 of bus bars 6a, 6b, the terminal 9 forms an extension of the metallic stripe 8. The terminal 9 of each of the two bus bars 6a, 6b comprises a tab 11a which protrudes sideways from the elongated metallic stripe.

In the third pair 12 of bus bars 6a, 6b, the terminal 9 is perpendicular to the metallic stripe 8. The first bus bar 6a of the third pair is inverted with respect to the second bus 6b bar of the third pair. The terminal 9 of the first bus bar 6a protrudes in an upward direction perpendicular to the metallic stripe 8 and the terminal 9 of the second bus bar 6b protrudes in a downward direction perpendicular to the metallic stripe 8.

In the fourth pair 13 of bus bars 6a, 6b, the terminal 9 comprises a first section 13a and a second section 13b similar to the first pair 10. The first section 13a of the terminal 9 is adjacent to the metallic stripe 8 of the main body. The second section 13b of the terminal 9 is adjacent to the first section 13a. Accordingly, the first section 13a is arranged between the second section 13b and the metallic stripe 8.

The first section 13a forms an obtuse angle relative to the metallic stripe 8. The obtuse angle can be, e.g., 10°. The second section 13b is parallel to the metallic stripe 8. The first section 13a provides an offset of the second section 13b relative to the metallic stripe 8. In the fourth pair 13, the offset is smaller compared to the offset in the first pair 10.

The four pairs 10-13 of bus bars 6a, 6b shown in FIG. 4 are examples of a multitude of pairs of bus bars which can be combined with the electronic device 1. Each of the bus bars 6a, 6b shown in FIG. 4 can be inserted into the housing 2. Each of the pairs of bus bars 6a, 6b provides a different terminal 9 for connection to a customer-designed interface.

FIG. 5 shows an arrangement wherein the bus bars 6a, 6b shown in FIG. 4 are fed through the electronic device 1 shown in FIG. 1. It is possible to feed different bus bars 6a, 6b through the electronic device 1. The electronic device 1 is compatible with different bus bars 6a, 6b. In particular, the arrangements shown in FIG. 5 differ in the position of the terminal 9 of the bus bars 6a, 6b.

The electronic device 1 can be standardized and combined with bus bars 6a, 6b of different shape to adapt for a connection to different customer-designed interfaces. The flexible bus bar constructions can be matched to the customer's requirements for its interface. No modifications of the electronic device 1 are necessary to adapt to a customer interface.

### REFERENCES

1 electronic device
2 housing
2a first end of the housing
2b second end of the housing
3 first guiding element
4 second guiding element
5 connection point
6a first bus bar
6b second bus bar
7 spring-loaded connection
8 metallic stripe
9 terminal
10 first pair
10a first section
10b second section
11 second pair
11a tab
12 third pair
13 fourth pair
13a first section
13b second section
17 motor
18 inverter
Cy electronic component, y capacitor
Cx electronic component, x capacitor
L electronic component, inductor

1. An electronic device comprising
a housing and at least one electronic component which is arranged inside the housing,
wherein the housing is suitable for feedthrough of at least one bus bar,
wherein the housing is compatible with bus bars of different shapes.

2. The electronic device according to claim 1,
wherein the housing is adapted such that the housing imposes no restrictions on the shape of a terminal of the at least one bus bar.

3. The electronic device according to claim 1,
wherein the housing comprises a guiding element suitable for feedthrough of the at least one bus bar, wherein the guiding element extends from a first end of the housing to a second end of the housing.

4. The electronic device according to claim 1,
wherein the housing comprises a fixation element configured to fix the at least one bus bar.

5. The electronic device according to claim 4,
wherein fixation element comprises a screw and/or a spring.

6. The electronic device according to claim 1,
wherein at least one of a capacitor and an inductor is arranged in the housing.

7. The electronic device according to claim 1,
wherein the electronic device is free from integrated bus bars.

8. The electronic device according to claim 1,
wherein the electronic device is an EMC filter.

9. The electronic device according to claim 1,
wherein the electronic device comprises a connection point inside the housing,
wherein the at least one electronic component is connected to the connection point, and
wherein the electronic device is configured such that the at least one bus bar is electrically connected to the connection point when being fed through the housing.

10. System comprising an electronic device according to claim 1, a first pair of bus bars and a second pair of bus bars,
wherein the first pair of bus bars and the second pair of bus bars differ in their shape,
wherein the housing of the electronic component is suitable for feedthrough of the first pair of bus bars and the housing of the electronic component is suitable for feedthrough of the second pair of bus bars.

11. System according to claim 10,
wherein each bus bar of the first pair of bus bars comprises a metallic strip and a terminal arranged at a first angle to the metallic strip,
wherein each bus bar of the second pair of bus bars comprises a metallic strip and a terminal arranged at a second angle to the metallic strip, wherein the second angle differs from the first angle.
